(19) United States
(12) Patent Application Publication
(10) Pub. No.: US 2007/0277731 A1
(43) Pub. Date: Dec. 6, 2007

(54) Method and apparatus for growing GaN bulk single crystals

(75) Inventor: Jal-yong Han, Suwon-si (KR)

Correspondence Address: HARNESS, DICKEY & PIERCE, P.L.C., P.O. BOX 8910, RESTON, VA, 20195, US

(73) Assignee: SAMSUNG CORNING CO., LTD.

(21) Appl. No.: 11/806,530

(22) Filed: Jun. 1, 2007

(30) Foreign Application Priority Data
Jun. 1, 2006 (KR) 10-2006-0049296

(51) Int. Cl. C30B 25/00; C30B 23/00; C30B 15/30

(52) U.S. Cl. 117/100; 117/202; 117/99

(57) ABSTRACT

Provided a method and an apparatus for growing high-quality GaN bulk single crystals without causing cracks. The method of growing GaN bulk single crystals includes providing a susceptor in a reaction chamber, providing a seed-accommodating portion having a given depth on an upper surface of the susceptor, providing GaN seeds on a bottom surface of the seed-accommodating portion so that only an upper surface of the GaN seeds is exposed, growing GaN bulk single crystals on the GaN seeds; and cooling the grown GaN bulk single crystals and separating the GaN bulk single crystals from the seed-accommodating portion.

### PRIORITY STATEMENT

This application claims the benefit of Korean Patent Application No. 10-2006-0049296, filed on Jun. 1, 2006, in the Korean Intellectual Property Office, the disclosure of which incorporated herein in its entirety by reference.

### BACKGROUND

1. Field

Example embodiments relate to a method and an apparatus for growing GaN bulk single crystals, and more particularly, to a method and an apparatus for growing high-quality GaN bulk single crystals.

2. Description of the Related Art

Gallium nitride (GaN) is a III-V compound semiconductor and has been widely used as a material for forming a semiconductor laser and a light emitting diode (LED) that operates in celadon green and ultraviolet ray regions. Such GaN may be manufactured on a different kind of substrate, such as a sapphire substrate having the same hexagonal structure or a silicon carbide (SiC) substrate, using a process, such as metal organic chemical vapor deposition (MOCVD) or molecular beam epitaxy (MBE).

However, because a lattice constant and/or a thermal expansion coefficient of a sapphire or SiC substrate are different from those of GaN crystals, a high crystal defect density may exist in grown GaN crystals. To solve the problem, high-quality GaN single crystals need to be used as a substrate. Currently, in order to make good-quality GaN single crystals at lower prices in mass production, large-diameter GaN bulk single crystals having thicknesses of several mm to several tens of mm are usually grown by using hydride vapor phase epitaxy (HVPE). That is, a flat susceptor on which GaN seeds are mounted is provided in a reaction chamber of an HVPE apparatus, and a source gas is supplied into the reaction chamber at about 1000° C. and therefore, GaN single crystals are grown on the GaN seeds. GaN bulk single crystals grown by HVPE may be cut in a proper size if necessary.

FIGS. 1A and 1B schematically illustrate a conventional process of growing GaN bulk single crystals on a flat susceptor. FIG. 1A illustrates the initial state of growth, and FIG. 1B illustrates the state after growth is completed. As illustrated in FIGS. 1A and 1B, according to HVPE, GaN bulk single crystals 11 are grown on a flat susceptor 10. However, GaN crystals 12 are grown on sides of the susceptor 10 and on circumference thereof. The GaN crystals 12 grown on the sides of the susceptor 10 become poly-crystals. In this case, the GaN single crystals 11 and the GaN poly-crystals 12 are connected to one another while growth is performed. Thus, the GaN single crystals 11 and the GaN poly-crystals 12 exist as one lump after growth is completed. This causes cracks in the GaN single crystals 11 during a cooling process after growth of the GaN single crystals 11 is completed. For example, after the GaN single crystals 11 are grown at a temperature of about 1000° C., the grown GaN single crystals 11 are cooled at a room temperature. In this case, because the thermal expansion coefficient of the GaN single crystals 11 is generally larger than that of the susceptor 10, the GaN single crystals 11 should contract faster than the susceptor 10. However, the GaN poly-crystals 12 adhered to the circumferences of the GaN single crystals 11 hinder contraction of the GaN single crystals 11 and therefore, cracks occur in the GaN single crystals 11.

As illustrated in FIGS. 2A and 2B, even when the diameter of the GaN bulk single crystals 11 is smaller than that of the susceptor 10, the GaN poly-crystals 12 are formed at edges of an upper surface of the exposed susceptor 10. Thus the above-mentioned problem may still exist. Further, because the growth speed of the GaN poly-crystals 12 is faster than that of the GaN single crystals 11 and the GaN poly-crystals 12 expands into the region of the GaN single crystals 11, the region of the GaN single crystals 11 may be decreased.

### SUMMARY

Example embodiments provide a method and an apparatus for growing high-quality GaN bulk single crystals.

Example embodiments provide a method and an apparatus for growing GaN bulk single crystals with a reduced number of cracks or without cracks.

According to example embodiments, there is provided a method of growing GaN bulk single crystals, the method including providing a susceptor in a reaction chamber, providing a seed-accommodating portion having a given depth on an upper surface of the susceptor, providing GaN seeds on a bottom surface of the seed-accommodating portion so that only an upper surface of the GaN seeds is exposed, growing GaN bulk single crystals on the GaN seeds, and cooling the grown GaN bulk single crystals and separating the GaN bulk single crystals from the seed-accommodating portion.

In example embodiments, a depth of the seed-accommodating portion may be within ±50% of a thickness of the GaN seeds.

In example embodiments, a depth of the seed-accommodating portion may be 500 μm.

In example embodiments, a distance between an inner wall of the seed-accommodating portion and the GaN seeds may be between 100 μm and 10 mm.

In example embodiments, the seed-accommodating portion may have one of a circular shape, an oval shape, and a polygonal shape, and the seed-accommodating portion and the GaN seeds may have the same shape.

In example embodiments, the susceptor may be formed of material which has heat resistance and does not react with GaN.

In example embodiments, the susceptor may be formed of a silicon carbide (SiC) or SiO₂ coated graphite.

In example embodiments, the growing of the GaN bulk single crystals may include: removing oxygen from the reaction chamber by flowing N₂ in the reaction chamber; and supplying an NH₃ gas and a GaCl gas as source gases into the reaction chamber while keeping a temperature of the reaction chamber at 1000° C.-1100° C.

According to example embodiments, there is provided an apparatus for growing GaN bulk single crystals, the apparatus including a reaction chamber, and a susceptor in the reaction chamber and a seed-accommodating portion having a given depth on an upper surface of the susceptor, so that when GaN seeds are provided on a bottom surface of the seed-accommodating portion, only an upper surface of GaN seeds within the reaction chamber is exposed.

In example embodiments, the seed-accommodating portion is part of the susceptor.

In example embodiments, the seed-accommodating portion is a separate unit from the susceptor.

### BRIEF DESCRIPTION OF THE DRAWINGS

The above and other aspects of example embodiments will become more apparent by describing them in detail with reference to the attached drawings in which:

FIGS. 1A and 1B are schematic cross-sectional views illustrating a conventional method of growing GaN bulk single crystals in a flat susceptor;

FIGS. 2A and 2B are schematic cross-sectional views illustrating another conventional method of growing GaN bulk single crystals in a flat susceptor;

FIG. 3 illustrates schematic structures of a hydride vapor phase epitaxy (HVPE) apparatus and a susceptor for growing GaN bulk single crystals according to example embodiments; and

FIGS. 4A and 4B are schematic cross-sectional views illustrating a method of growing GaN bulk single crystals in the susceptor illustrated in FIG. 3, according to example embodiments.

### DETAILED DESCRIPTION

Example embodiments will be more clearly understood from the detailed description taken in conjunction with the accompanying drawings.

Various example embodiments will now be described more fully with reference to the accompanying drawings in which some example embodiments of the invention are shown. In the drawings, the thicknesses of layers and regions may be exaggerated for clarity.

Detailed illustrative embodiments are disclosed herein. However, specific structural and functional details disclosed herein are merely representative for purposes of describing example embodiments. This invention may, however, may be embodied in many alternate forms and should not be construed as limited to only the embodiments set forth herein.

Accordingly, while example embodiments of the invention are capable of various modifications and alternative forms, embodiments thereof are shown by way of example in the drawings and will herein be described in detail. It should be understood, however, that there is no intent to limit example embodiments of the invention to the particular forms disclosed, but on the contrary, example embodiments of the invention are to cover all modifications, equivalents, and alternatives falling within the scope of the invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of example embodiments of the invention. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the FIGS. For example, two FIGS. shown in succession may in fact be executed substantially concurrently or may sometimes be executed in the reverse order, depending upon the functionality/acts involved.

Also, the use of the words “compound,” “compounds,” or “compound(s),” refer to either a single compound or to a plurality of compounds. These words are used to denote one or more compounds but may also just indicate a single compound.

Example embodiments will be described in detail with reference to the attached drawings. However, the present invention is not limited to example embodiments, but may be embodied in various forms. In the figures, if a layer is formed on another layer or a substrate, it means that the layer is directly formed on another layer or a substrate, or that a third layer is interposed therebetween. In the following description, the same reference numerals denote the same elements.

Although example embodiments have been disclosed for illustrative purposes, those skilled in the art will appreciate that various modifications, additions and substitutions are possible, without departing from the scope and spirit of the invention as disclosed in the accompanying claims.

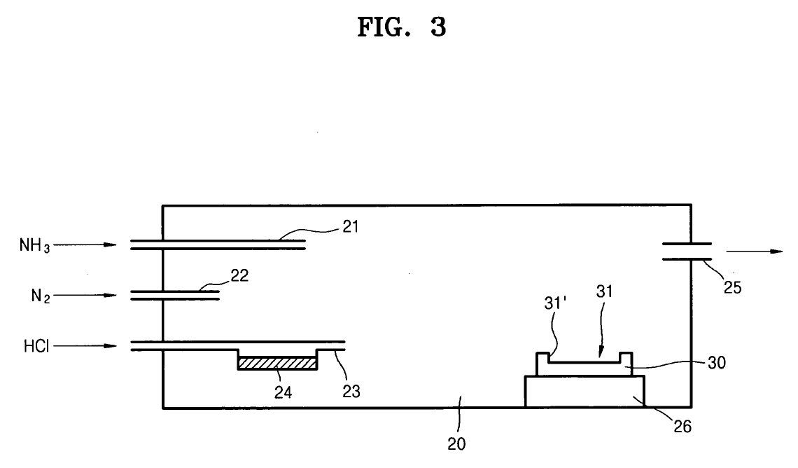

FIG. 3 illustrates schematic structures of a hydride vapor phase epitaxy (HVPE) apparatus and a susceptor for growing GaN bulk single crystals according to example embodiments.

As described previously, GaN bulk single crystals are generally grown using a hydride vapor phase epitaxy (HVPE) apparatus. The apparatus for growing GaN bulk single crystals illustrated in FIG. 3 may be a kind of HVPE apparatus. As illustrated in FIG. 3, the apparatus for growing GaN bulk single crystals may include a reaction chamber 20 in which a high-temperature chemical reaction is performed, a first gas inlet tube 21 penetrating a side of the reaction chamber 20 and supplying an NH₃ gas into the reaction chamber 20, a second gas inlet tube 22 penetrating a side of the reaction chamber 20 and supplying an N₂ gas into the reaction chamber 20, a third gas inlet tube 23 penetrating a side of the reaction chamber 20 and supplying an HCl gas into the reaction chamber 20, a gallium source storing unit 24 connected to the third gas inlet tube 23 and supplying gallium to the HCl gas, a gas exhaustion tube 25 exhausting a gas inside the reaction chamber 20 to the outside, a susceptor 30 on which GaN seeds may be provided and GaN bulk single crystals are to be grown, and a susceptor support 26 located in the reaction chamber 20 and supporting the susceptor 30.

In example embodiments, the susceptor 30 may be formed of a material which has heat resistance and does not react with GaN. For example, the susceptor 30 may be formed of silicon carbide (SiC) or SiO₂ coated graphite.

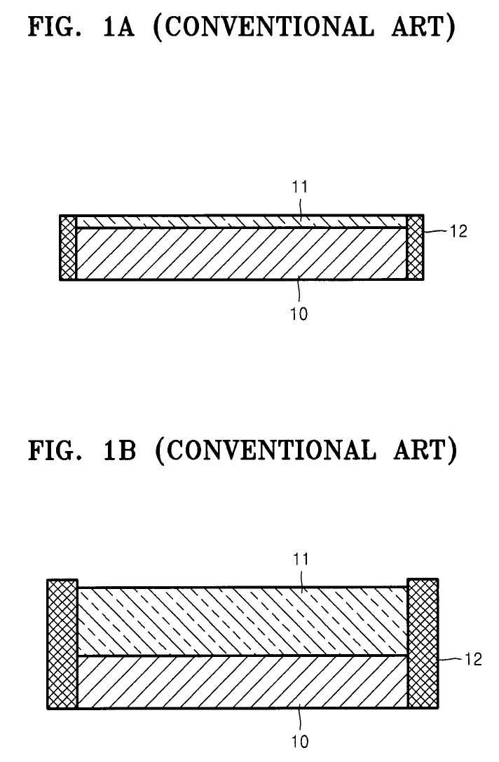

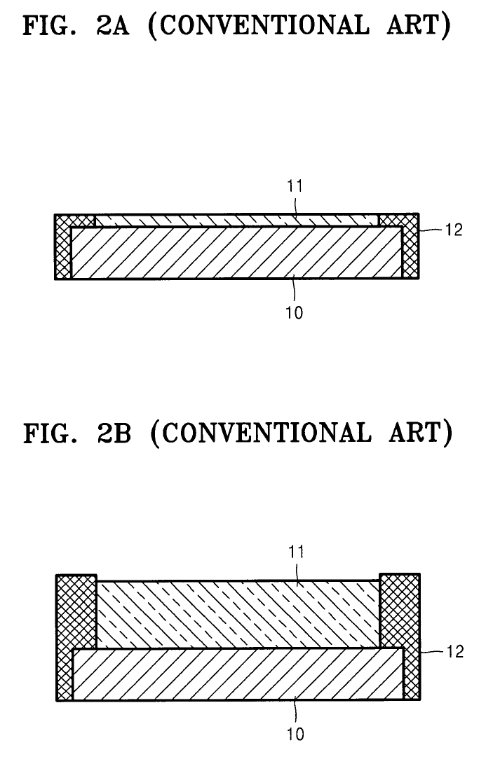

As described with reference to FIGS. 1A through 2B, conventionally, a susceptor 10 having a completely flat upper surface is used. As a result, there is a problem in which cracks occur in GaN bulk single crystals during a cooling process due to GaN poly-crystals grown on sides of the susceptor 10. To reduce or prevent the occurrence of the problem, in example embodiments, a seed-accommodating portion 31 with a recess of a given depth, may be disposed on an upper surface of the susceptor 30, as illustrated in FIG. 3, and GaN seeds may be provided on a bottom surface of the seed-accommodating portion 31. The seed-accommodating portion 31 may serve to expose only an upper surface of the GaN seeds within the reaction chamber 20 when the susceptor 30 having the GaN seeds is provided in the reaction chamber 20. To this end, the depth of the seed-accommodating portion 31 may be about within ±50% of the thickness of the GaN seeds.

If a distance between an inner wall 31′ of the seed-accommodating portion 31 and the GaN seeds is too far, sides of the GaN seeds are substantially exposed. Thus, GaN poly-crystals may also be grown on the sides of the GaN seeds. In addition, if the distance between the inner wall 31′ of the seed-accommodating portion 31 and the GaN seeds is too small, GaN poly-crystals formed on the sides of the susceptor 30 and GaN bulk single crystals grown on the seed-accommodating portion 31 may also be connected to one another. In these cases, cracks may occur in the GaN bulk single crystals during a cooling process. Thus, the distance between the inner wall 31′ of the seed-accommodating portion 31 and the GaN seeds needs to be maintained. In example embodiments, the distance between the inner wall 31′ of the seed-accommodating portion 31 and the GaN seeds may be between 100 μm and 10 mm.

For example, when GaN seeds having the thickness of about 500 μm and a diameter of about 2 inches are used, the depth of the seed-accommodating portion 31 of the susceptor 30 may be about 500 μm and the diameter thereof may be about 52 mm. In example embodiments, the shape of the seed-accommodating portion 31 does not heed to be circular and the seed-accommodating portion 31 may be formed in various shapes according to the shape of the GaN seeds. For example, the seed-accommodating portion 31 may have one of a circular shape, an oval shape, and a polygonal shape according to the shape of the GaN seeds.

A method of growing GaN bulk single crystals using an apparatus for forming GaN bulk single crystals and the susceptor 30 illustrated in FIG. 3 will now be described.

A susceptor 30 in which a seed-accommodating portion 31 having the depth of about 500 μm, for example, and having the diameter of about 52 mm, for example, may be provided. GaN seeds having a thickness of about 500 μm and a diameter of about 2 inches may be provided on a bottom surface of the seed-accommodating portion 31 of the susceptor 30. In example embodiments, the inner wall 31′ of the seed-accommodating portion 31 and the GaN seeds may be spaced apart from each other by a gap of about 1 mm. The susceptor 30 on which the GaN seeds are provided may be fixed on the susceptor support 26 in the reaction chamber 20.

An N₂ gas may be provided to the reaction chamber 20 through the second gas inlet tube 22 and therefore, oxygen existing in the reaction chamber 20 may be removed. After oxygen is removed, the temperature of the reaction chamber 20 may be maintained at about 1000° C.-1100° C., for example, at about 1050° C. An NH₃ gas may be supplied into the reaction chamber 20 through the first gas inlet tube 21 and simultaneously, an HCl gas may be supplied into the reaction chamber 20 through the third gas inlet tube 23. In example embodiments, the HCl gas supplied through the third gas inlet tube 23 may combine with a gallium source in the gallium source storing unit 24 connected to the third gas inlet tube 23. GaCl formed as a result of the combination may flow into the reaction chamber 20 through the third gas inlet tube 23.

The NH₃ gas and the GaCl gas in the reaction chamber 20 contact the GaN seeds on the susceptor 30 so that GaN single crystals start growing on the GaN seeds. Generally, the growth speed of the GaN single crystals by a growth method according to example embodiments may be about 50-500 μm/hr. By growing the GaN single crystals for about several tens of hours in this way, GaN bulk single crystals having a thickness of several mm to several tens of mm may be obtained. For example, when the GaN single crystals are grown for about 10 hours, GaN bulk single crystals having a thickness of about 5 mm may be obtained.

If growth of the GaN bulk single crystals is completed in this manner, the temperature of the reaction chamber 20 may be reduced to room temperature and the susceptor 30 may be removed from the reaction chamber 20. GaN poly-crystals on sides of the susceptor 30 may be removed, and the GaN bulk single crystals grown within the seed-accommodating portion 31 may be separated from the susceptor 30.

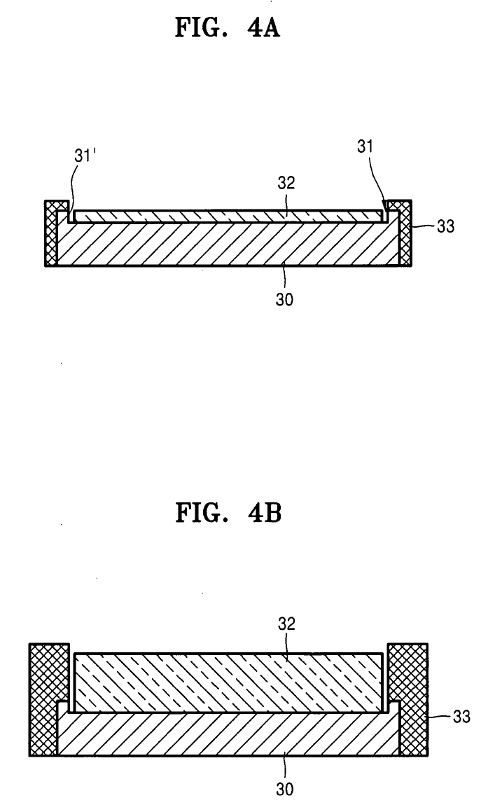

According to example embodiments, because the recessed seed-accommodating portion 31 may be disposed in the susceptor 30, cracks do not occur (or a reduced number of cracks occur) in the GaN bulk single crystals whose growth is completed, even during the cooling process. FIGS. 4A and 4B are cross-sectional views for explaining a principle in which the seed-accommodating portion 31 reduces or prevents cracks. FIG. 4A illustrates the initial state of growth, and FIG. 4B illustrates the state after growth is completed.

As described previously, cracks occur due to GaN poly-crystals adhered to sides of GaN bulk single crystals. In example embodiments, because GaN seeds are provided on the recessed seed-accommodating portion 31 of the susceptor 30, only an upper surface of GaN bulk single crystals 32 at the initial state of growth are exposed and sides thereof are not exposed, as illustrated in FIG. 4A. Thus, GaN poly-crystals are not grown on sides of the GaN seeds and GaN poly-crystals 33 grown on sides of the susceptor 30 are also not connected to the GaN bulk single crystals 32. To this end, as described previously, the distance between the inner wall 31′ of the seed-accommodating portion 31 and the GaN seeds may be between 100 μm and 10 mm. In addition, because GaN single crystals or poly-crystals tend to be grown in a vertical direction (generally, the growth speed in the vertical direction is over 5 times faster than the growth speed in a horizontal direction), the GaN bulk single crystals 32 and the GaN poly-crystals 33 do not adhere to one another and may be independently grown even while growth is performed. As such, the GaN bulk single crystals 32 and the GaN poly-crystals 33 do not adhere to one another and may be independently grown even after growth is completed, as illustrated in FIG. 4B. Thus, contraction of the GaN bulk single crystals 32 is not hindered by the GaN poly-crystals 33 during the cooling process so that fewer or no cracks occur in the GaN bulk single crystals 32.

According to example embodiments, the GaN poly-crystals 33 do not adhere to the GaN bulk single crystals 32 while the GaN bulk single crystals 32 are grown. Because cracks do not occur in the GaN bulk single crystals 32 during the cooling process, higher-quality GaN bulk single crystals 32 may be obtained. In addition, because the GaN single crystals 33 do not adhere to the GaN bulk single crystals 32, the GaN bulk single crystals 32 whose growth is completed, may easily be separated from the susceptor 30.

In example embodiments, the seed-accommodating portion 31 is described as being part of the susceptor 30. However, in other example embodiments, the seed-accommodating portion 31 may be part of another structure or a separate structure.

While example embodiments have been particularly shown and described, it will be understood by those of ordinary skill in the art that various changes in form and details may be made therein without departing from the spirit and scope of example embodiments as defined by the following claims.

What is claimed is:

1. A method of growing GaN bulk single crystals, the method comprising:
providing a susceptor in a reaction chamber;
providing a seed-accommodating portion having a given depth on an upper surface of the susceptor; and
providing GaN seeds on a bottom surface of the seed-accommodating portion so that only an upper surface of the GaN seeds is exposed;
growing GaN bulk single crystals on the GaN seeds; and
cooling the grown GaN bulk single crystals and separating the GaN bulk single crystals from the seed-accommodating portion.

2. The method of claim 1, wherein a depth of the seed-accommodating portion is within ±50% of a thickness of the GaN seeds.

3. The method of claim 2, wherein a depth of the seed-accommodating portion is 500 μm.

4. The method of claim 1, wherein a distance between an inner wall of the seed-accommodating portion and the GaN seeds is between 100 μm and 10 mm.

5. The method of claim 4, wherein the seed-accommodating portion has one of a circular shape, an oval shape, and a polygonal shape, and the seed-accommodating portion and the GaN seeds have the same shape.

6. The method of claim 1, wherein the susceptor is formed of a material which has heat resistance and does not react with GaN.

7. The method of claim 6, wherein the susceptor is formed of a silicon carbide (SiC) or SiO₂ coated graphite.

8. The method of claim 1, wherein the growing of the GaN bulk single crystals comprises:
removing oxygen in the reaction chamber by flowing N₂ from the reaction chamber; and
supplying an NH₃ gas and a GaCl gas as source gases into the reaction chamber while keeping a temperature of the reaction chamber at 1000° C.-1100° C.

9. An apparatus for growing GaN bulk single crystals, the apparatus comprising:
a reaction chamber, and
a susceptor in the reaction chamber; and
a seed-accommodating portion having a given depth on an upper surface of the susceptor, so that when GaN seeds are provided on a bottom surface of the seed-accommodating portion, only an upper surface of GaN seeds within the reaction chamber is exposed.

10. The apparatus of claim 9, wherein a depth of the seed-accommodating unit is within ±50% of a thickness of the GaN seeds.

11. The apparatus of claim 10, wherein a depth of the seed-accommodating portion is 500 μm.

12. The apparatus of claim 9, wherein a distance between an inner wall of the seed-accommodating portion and the GaN seeds is between 100 μm and 10 mm.

13. The apparatus of claim 12, wherein the seed-accommodating portion has one of a circular shape, an oval shape, and a polygonal shape, and the seed-accommodating portion and the GaN seeds have the same shape.

14. The apparatus of claim 9, wherein the susceptor is formed of a material which has heat resistance and does not react with GaN.

15. The apparatus of claim 14, wherein the susceptor is formed of a silicon carbide (SiC) or SiO₂ coated graphite.

16. The apparatus of claim 9, further comprising:
a first gas inlet tube supplying an NH₃ gas into the reaction chamber;
a second gas inlet tube supplying an N₂ gas into the reaction chamber;
a third gas inlet tube supplying an HCl gas into the reaction chamber;
a gallium source storing unit connected to the third gas inlet tube; and
a gas exhaustion tube exhausting a gas in the reaction chamber.

17. The apparatus of claim 9, wherein the seed-accommodating portion is part of the susceptor.

18. The apparatus of claim 9, wherein the seed-accommodating portion is a separate unit from the susceptor.
